(19) United States
(12) Patent Application Publication
(10) Pub. No.: US 2011/0157810 A1
(43) Pub. Date: Jun. 30, 2011

(54) SERVER WITH A REPLACEABLE MODULE

(75) Inventor: Tse-Min LIN, Sijhih City/Taipei County (TW)

(73) Assignee: LANNER ELECTRONIC INC., Sijhih City/Taipei County (TW)

(21) Appl. No.: 12/649,284

(22) Filed: Dec. 29, 2009

(51) Int. Cl. H05K 7/10

(52) U.S. Cl. 361/679.32

(57) ABSTRACT

A server with a replaceable module includes a housing, at least one carrying mechanism and at least two urging units. The carrying mechanism further has a carrying seat, a first cover plate, at least two retaining plates and at least two fastening members. Each of the two urging units has a second notch and an exerting portion. Therein, when a user exerts a force on the exerting portions, the fastening members are ejected out form the housing, and the carrying mechanism is ejected out of the housing simultaneously.

### BACKGROUND OF THE INVENTION

1. Technical Field

The present invention relates to a server and more particularly, to a server with a replaceable module, which has effort-saving urging units.

2. Description of Related Art

In recent years, due to the progress of information technology and the popularization of computer network use, various applications about servers have been increasingly developed. Principally, a server is a core computer in a network system for serving other computers in the system. It provides functions of web-drive or web-printer desired by network users, while allowing user terminals to share resources in the network environment. A server has a basic structure that is substantially similar to a general personal computer, being composed of at least one CPU, at least one memory and at least one I/O device that are connected by a plurality of Buses inside the server.

A conventional server is composed of a motherboard, a CPU and at least one hard drive, with or without other electronic devices, which are all fixed in an accommodating space inside a housing by means of screws. A cover plate is used to close an opening of the housing, for preventing dust and foreign matters invading and damaging the electronic devices. However, in each time of inner mechanical maintenance, only when the cover plate is removed, a hand tool is allowed to enter the inner accommodating space for operation, and this is likely to cause the electronic devices in the server impacted or damaged.

In view of the shortcomings as described above, some improvements have been made to conventional servers. Referring to FIG. 1, an improved structure of a conventional server A is illustrated. A specific electronic device, such as a motherboard A1 is settled on a carrying mechanism A2, and the carrying mechanism A2 is inserted and received in the housing A3 through an opening A4 of the housing A3. When maintenance of the motherboard A1 has to be carried out, the motherboard A1 can be easily accessed by drawing out the carrying mechanism A2 from the housing A3. For drawing out the carrying mechanism A2, a force has to be applied to one or more pulling handles A5, A6 (herein one provided at each side) set at the outer surface of the carrying mechanism A2 and drives the carrying mechanism A2 outward. However, in this way, only a relatively large force can work to draw out the carrying mechanism A2. Besides, an unevenly exerted force may break links between the motherboard A1 and other components, damaging the server A.

Thus, there is a need for an effort-saving mechanism for a server. The effort-saving mechanism facilitates drawing operation of the carrying mechanism and ensures integrity of links between electronic devices.

### BRIEF SUMMARY OF THE INVENTION

In view of the defects of the prior art, the inventor of the present invention implemented his years of experience, imagination and creativity, after numerous tests and modifications, and has eventually developed a server with a replaceable module.

A first objective of the present invention is to provide a server with a replaceable module, which employs an effort-saving means to draw a carrying mechanism, wherein urging units having two through holes and the carrying mechanism having two fastening members cooperate to achieve effort-saving drawing operation.

A second objective of the present invention is to provide a server with a replaceable module, which employs an effort-saving means to draw a carrying mechanism, wherein urging units having two bent segments and a carrying mechanism having two fastening members cooperate to achieve effort-saving drawing operation.

A third objective of the present invention is to provide a server with a replaceable module, which employs an effort-saving means to draw a carrying mechanism, wherein urging units having two through holes and a carrying mechanism having two fastening members as well as at least one pulling handle cooperate to achieve effort-saving drawing operation.

The present invention discloses a server with a replaceable module. The server comprises: a housing formed at on lateral thereof with a first opening that intercommunicates with an inner accommodating space; at least one carrying mechanism, installed in the inner accommodating space through the first opening of the housing, the carrying mechanism further including: a carrying seat, configured to carry at least one motherboard; a first cover plate, perpendicularly connected with the carrying seat, when the carrying mechanism is installed in the inner accommodating space of the housing, the first cover plate rightly covering the first opening so as to prevent foreign matters from entering the inner accommodating space of the housing; at least two retaining plates, settled at two sides of the first cover plate, when the carrying seat is installed in the inner accommodating space of the housing, the two retaining plates contacting surfaces of the housing at two sides of the first opening, so as to position the carrying mechanism at a specific position without sway or displacement, and allow a user to exert a force on the two retaining plates to draw out the carrying mechanism form the inner accommodating space of the housing; and at least two fastening members, arranged at two sides of the carrying seat, each of the two fastening members having a first notch tailed by a bent segment provided at an end far from the first cover plate; and at least two urging units, pivotally provided at two opposite inner lateral surfaces of the housing adjacent to the first opening and each having: a second notch, configured to engage with the bent segment of a corresponding said fastening members; and a exerting portion, having a through hole that allows the user to exert a force thereon to drive the urging unit to rotate, wherein when the urging unit is rotated, engagement between the second notch and the bent segment makes the fastening member be ejected out of the housing and the carrying mechanism is ejected from the housing simultaneously.

### BRIEF DESCRIPTION OF THE SEVERAL VIEWS OF THE DRAWINGS

The invention as well as a preferred mode of use and advantages thereof will be best understood by referring to the following detailed description of the illustrative embodiments in conjunction with the accompanying drawings, wherein:

FIG. 1 illustrates a conventional server structure;

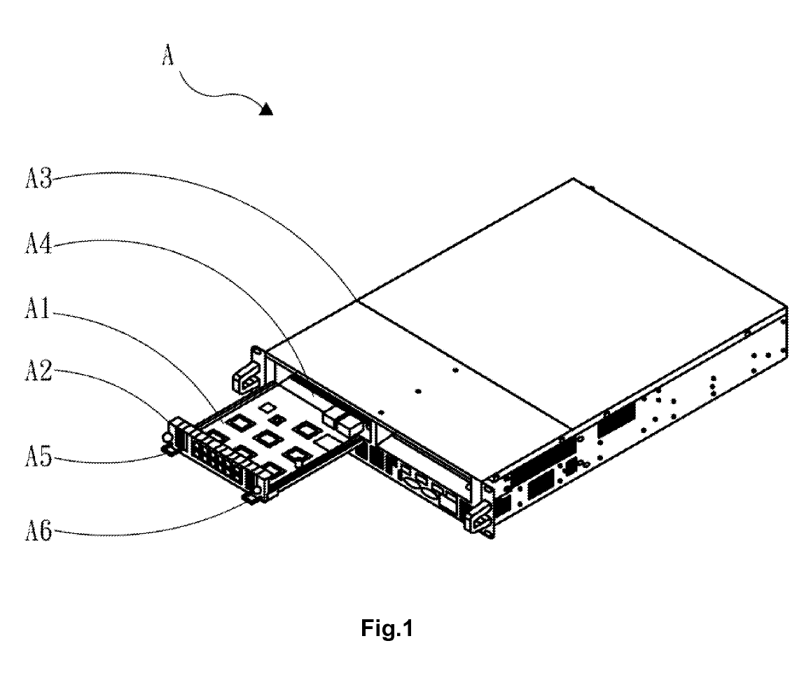

FIG. 2 is a perspective view of a server according to a first preferred embodiment of the present invention;

FIG. 3 is a perspective view of the server of FIG. 2 with a second cover plate removed;

FIG. 4 is an enlarged view of the server of FIG. 3;

FIG. 5 is an enlarged view of a carrying mechanism according to the first preferred embodiment of the present invention;

FIG. 6 is a schematic drawing showing engagement of a fastening member and an urging unit according to the first preferred embodiment of the present invention;

FIGS. 7A, 7B, 7C are schematic drawings showing how the urging unit ejects the fastening member according to the present invention;

FIGS. 8A and 8B show variations of the urging unit according to the first preferred embodiment of the present invention;

FIG. 9 is a perspective view of an urging unit according to a second preferred embodiment of the present invention; and

FIG. 10 is a perspective view of a server according to a third preferred embodiment of the present invention.

### DETAILED DESCRIPTION OF THE INVENTION

For achieving the foregoing objectives and effects, the inventor combines a server structure and an effort-saving mechanism, with ceaseless correction and modification, to provide a server with a replaceable module of the present invention. Hereinafter, a server with a replaceable module according to a first preferred embodiment, a server with a replaceable module according to a second preferred embodiment, and a server with a replaceable module according to a third preferred embodiment will be described in detail for illustrating the structural features and principles of the present invention.

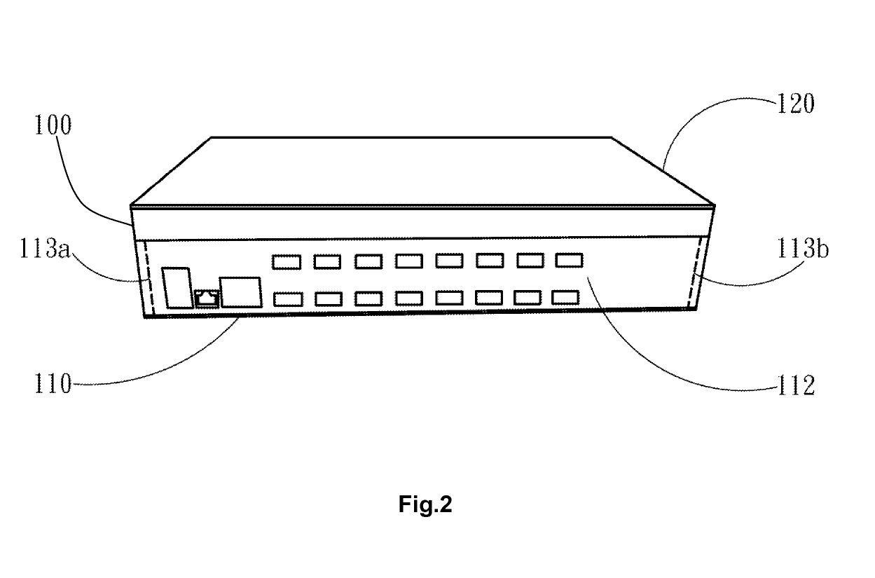

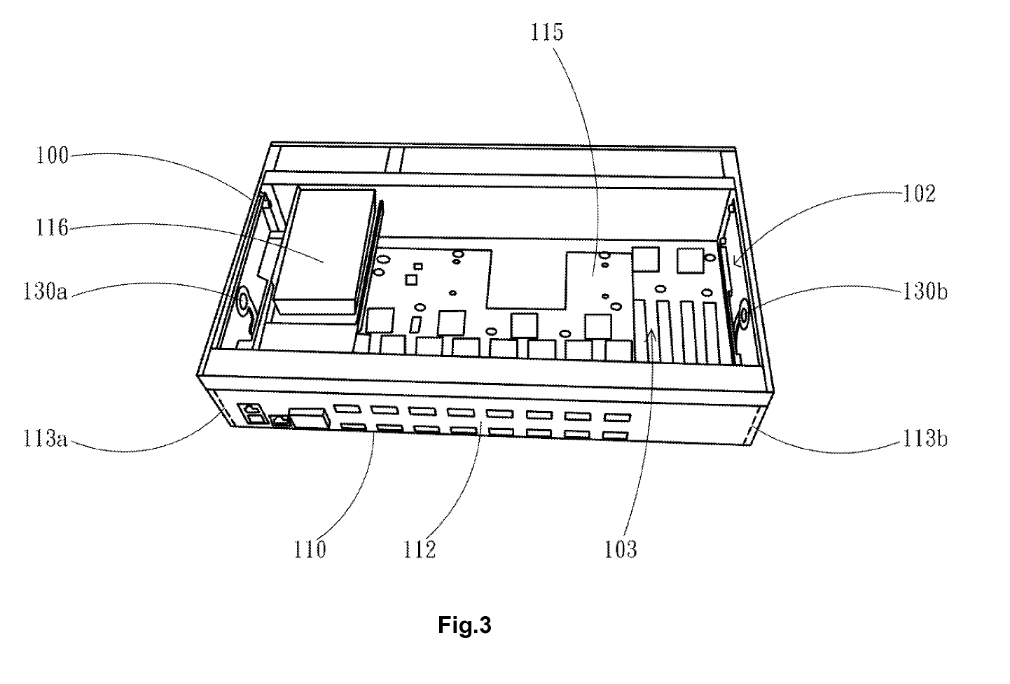

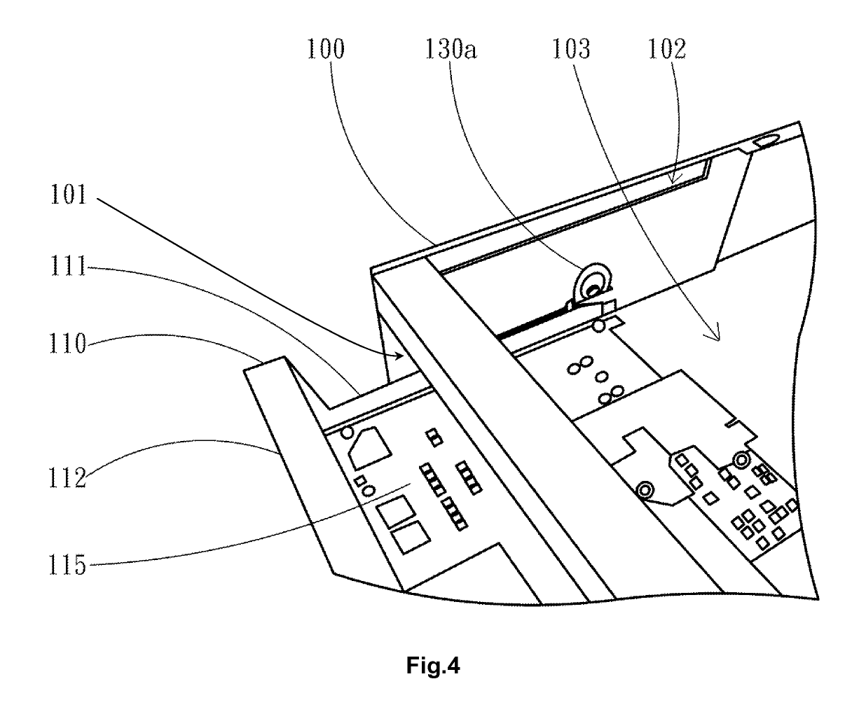

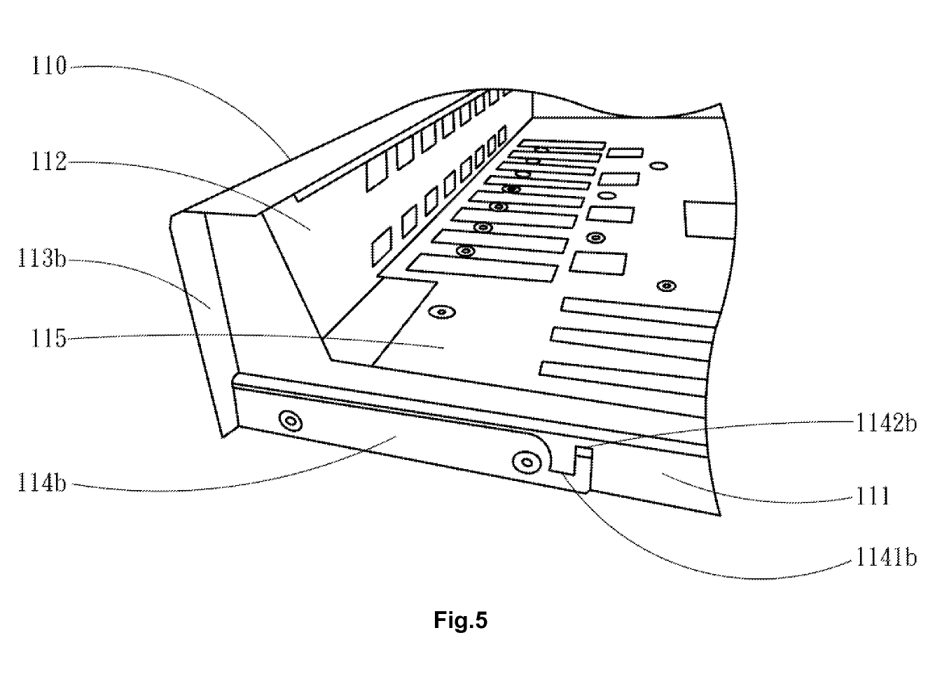

Please refer to FIG. 2, FIG. 3, FIG. 4 and FIG. 5. FIG. 2 is a perspective view of the server according to the first preferred embodiment of the present invention. FIG. 3 is a perspective view of the server of FIG. 2 with a second cover plate removed. FIG. 4 is an enlarged view of the server of FIG. 3. FIG. 5 is an enlarged view of a carrying mechanism according to the first preferred embodiment of the present invention. The server with the replaceable module primarily comprises: a housing 100, a carrying mechanism 110, a second cover plate 120, and two urging units 130a, 130b.

The housing 100 has a first opening 101 and a second opening 102 located at lateral and a top thereof, respectively. Through the first opening 101 and the second opening 102, an inner accommodating space 103 is accessible.

The carrying mechanism 110 is settled in the inner accommodating space 103 through the first opening 101 of the housing 100. The carrying mechanism 110 further has a carrying seat 111, a first cover plate 112, two retaining plates 113a, 113b and two fastening members (only one said fastening member, i.e. 114b, shown in the drawings). The carrying seat 111 is configured to carry a motherboard 115 thereon. At least one electronic device may be provided on the motherboard 115 for extension of function of the server. The electronic device may comprise a central processing unit (CPU), a hard drive, a random access memory (RAM), a fan and a network interface card. In the present preferred embodiment, a hard drive 116 is provided on the motherboard 115. The first cover plate 112 is perpendicularly connected with the carrying seat 111. When the carrying seat 111 is installed in the inner accommodating space 103 of the housing 100, the first cover plate 112 can rightly cover the first opening 101, so as to prevent foreign matters from entering the inner accommodating space 103 of the housing 100. The two retaining plates 113a, 113b are set at two sides of the first cover plate 112. When the carrying seat 111 is installed in the inner accommodating space 103 of the housing 100, the two retaining plates 113a, 113b come into contact with surfaces of the housing 100 at two sides of the first opening 101, so as to position the carrying mechanism 110 at a specific position without sway and displacement. Furthermore, a user may exert a force on the two retaining plates 113a, 113b for drawing out the carrying mechanism 110 from the inner accommodating space 103 of the housing 100. The two fastening members (only one said fastening member 114b shown in the drawing) are provided at two sides of the carrying seat 111. The fastening member 114b has a first notch 1141b tailed by a bent segment 1142b provided at an end far from the first cover plate 112.

The second cover plate 120 is configured to cover the second opening 102, so as to protect articles in the inner accommodating space 103. The second cover plate 120 may be fastened to the housing 100 by means of screws, soldering, magnetic attraction or wedge means.

The two urging units 130a, 130b are pivotally provided at two opposite inner lateral surfaces of the housing 100 adjacent to the first opening 101.

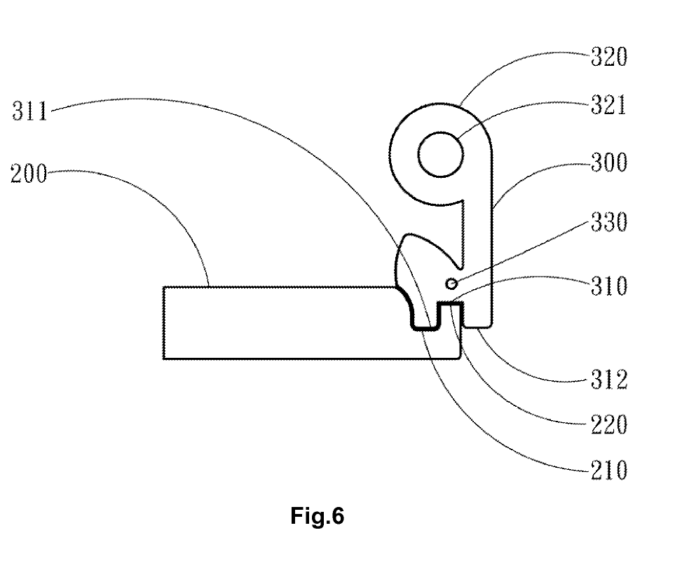

Please refer to FIG. 6 for a schematic drawing showing engagement of a fastening member 200 and an urging unit 300. As can be seen in the drawing, the urging unit 300 further comprises a second notch 310, an exerting portion 320 and a pivotal hole 330. The second notch 310 is configured to wedge the bent segment 220 of the fastening members 200. A first cape 311 and a second cape 312 are formed at two sides of the second notch 310. The exerting portion 320 has a through hole 321 that facilitates a user to exert a force on and thereby lever the urging unit 300. Through the engagement between the second notch 310 and the bent segment 220, when the urging unit 300 is levered, the fastening member 200 is ejected out of the housing (not shown), and the carrying mechanism (not shown) is also expelled outward from the housing.

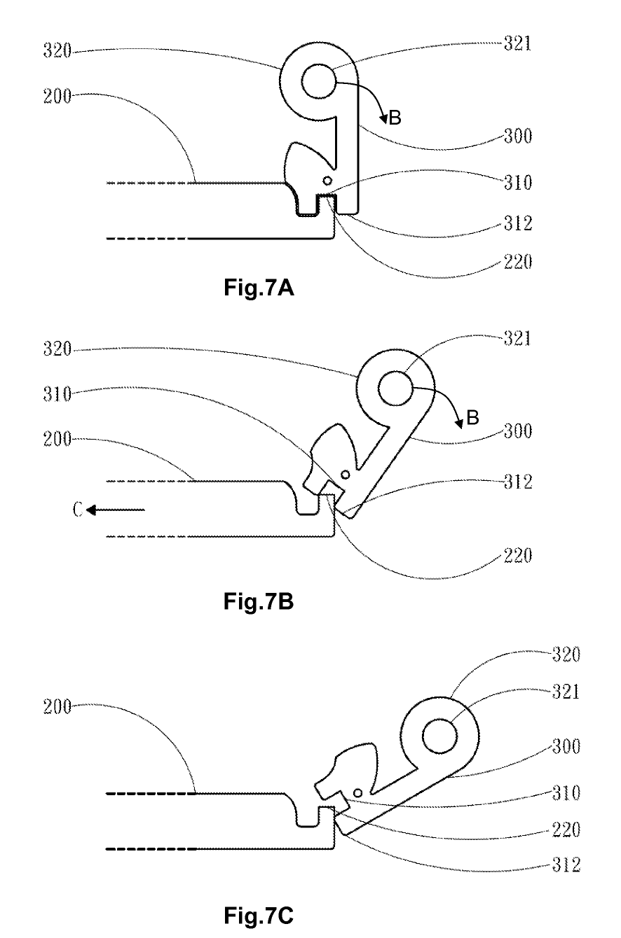

Referring to FIGS. 7A, 7B and 7C, how the urging unit 300 ejects the fastening member 200 is shown therein. In FIG. 7A, the second notch 310 of the urging unit 300 is engaged with the bent segment 220 of the fastening member 200. Then a force exerted through the through hole 321 of the exerting portion 320 along a direction shown by Arrow B in the drawing, the urging unit 300 rotates clockwise as shown in FIG. 7B so as to make the second notch 310 of the urging unit 300 and the bent segment 220 of the fastening member 200 start to disengage from each other, and in turn make the second cape 312 to eject the fastening member 200 along a direction shown by Arrow C. When the urging unit 300 moves to a position as shown in FIG. 7C, the urging unit 300 and the fastening member 200 are now disengaged completely. At this time, since the fastening member 200 has been pushed out by the second cape 312 for a small distance, the user can use the two retaining plates (not shown) of the carrying mechanism (not shown) to easily pull out the carrying mechanism. On the contrary, when the user pushes the carrying mechanism into the inner accommodating space (not shown) of the housing (not shown), the bent segment 220 of the fastening member 200 moves inward and thus lifts the second cape 312 of the urging unit 300, so that the urging unit 300 is anticlockwise rotated. Eventually, when the bent segment 220 of the fastening member 200 and the second notch 310 of the urging unit 300 engage mutually again, the carrying mechanism is positioned in the inner accommodating space of the housing firmly.

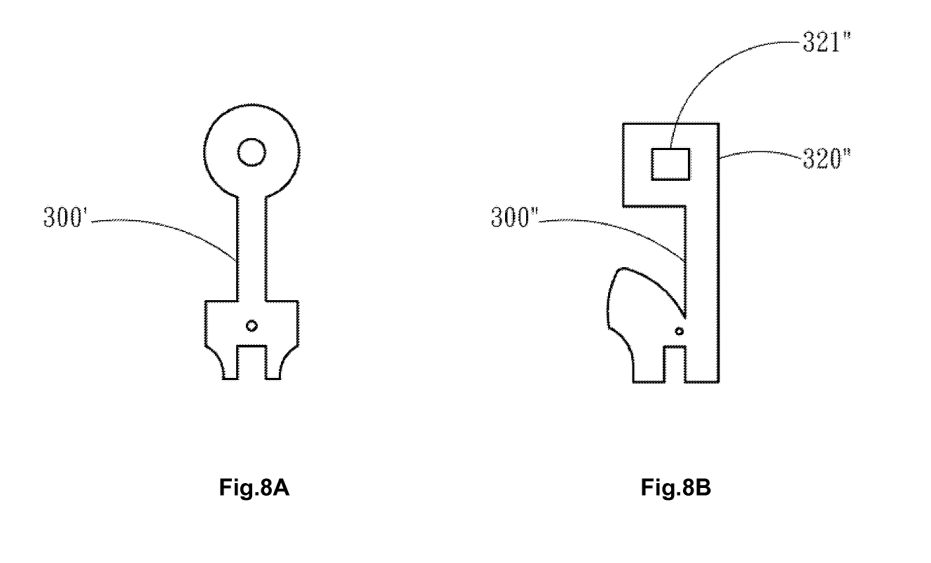

In the first preferred embodiment, the shape of the urging unit may be modified. FIGS. 8A and 8B show variations of the urging unit in the first preferred embodiment. The urging unit 300′ in FIG. 8A has an axially symmetrical shape while the urging unit 300″ in FIG. 8B has a rectangle exerting portion 320″ and a rectangle through hole 321″.

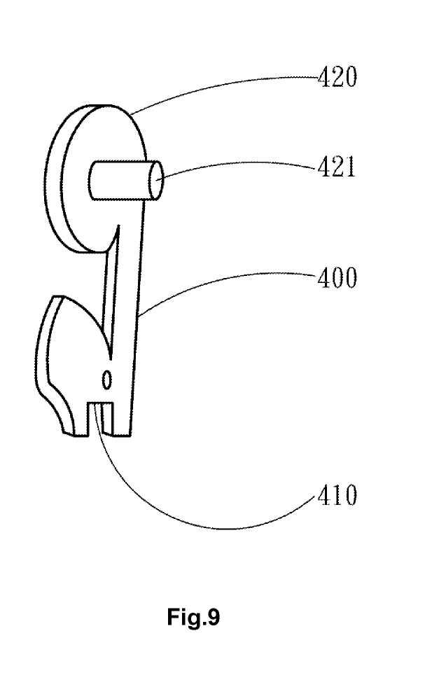

Referring to FIG. 9, a perspective view of an urging unit according to a second preferred embodiment of the present invention is shown. While the second preferred embodiment copies most structural features of the first preferred embodiment, the counterparts existing in both said embodiments will not be discussed in any length herein. The second preferred embodiment, differently, has an urging unit 400 having a exerting portion 420 provided with a rotational post 421, allowing a user to exert a force on the rotational post 421 so as to lever the urging unit 400. In virtue of the engagement between the second notch 410 and the bent segment (not shown) of the fastening member (not shown), the fastening member is ejected out of the housing (not shown), and the carrying mechanism (not shown) is also expelled from the housing.

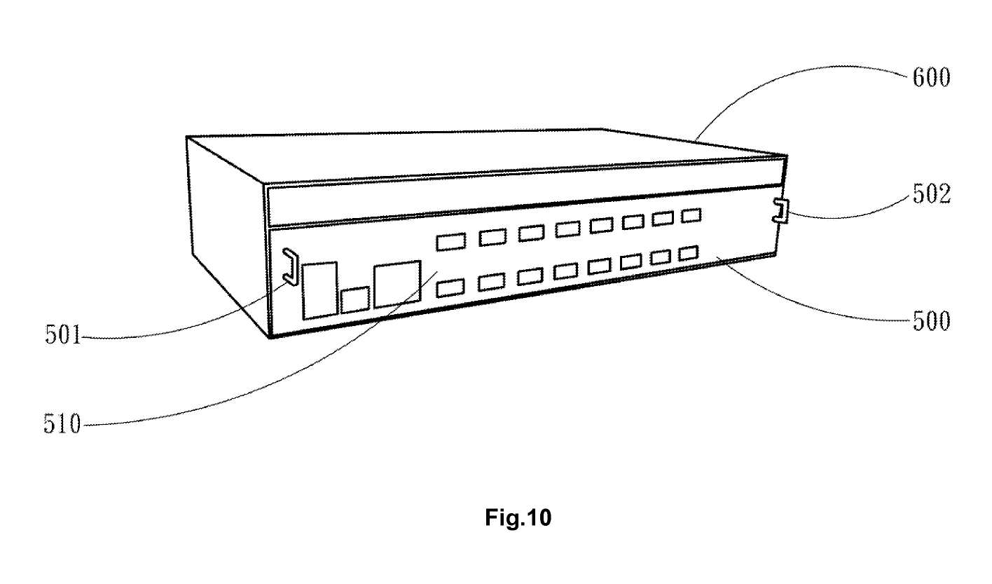

FIG. 10 is a perspective view of a server according to a third preferred embodiment of the present invention. While the third preferred embodiment copies most structural features of the first preferred embodiment, the counterparts existing in both said embodiments will not be discussed in any length herein. The third preferred embodiment, differently, has a carrying mechanism 500 including two pulling handles 501, 502, which are arranged at an outer surface of a first cover plate 510, so that a user can exert a force on the pulling handles 501, 502 to draw out the carrying mechanism 500 from the inner accommodating space (not shown) of the housing 600, or to push the carrying mechanism 500 back into the inner accommodating space of the housing 600.

Through the above detailed description to the structure and features of the present invention, it is summarized that the present invention has the following advantages:
1. The present invention implements the two urging units and two fastening members together to realize an effort-saving means for ejecting out the carrying mechanism, so as to facilitate maintenance of the motherboard or other electronic devices.
2. The present invention uses the urging units to push out the fastening members so that the pushing force is relatively even and therefore prevent connections between the motherboard and ports from being damaged.
3. The present invention employs the engagement between the urging units and the fastening members to ensure that the carrying mechanism is well positioned in the inner accommodating space of the housing, without sway or looseness.

The embodiments described above are intended only to demonstrate the technical concept and features of the present invention so as to enable a person skilled in the art to understand and implement the contents disclosed herein. It is understood that the disclosed embodiments are not to limit the scope of the present invention. Therefore, all equivalent changes or modifications based on the concept of the present invention should be encompassed by the appended claims.

What is claimed is:

1. A server with a replaceable module, the server comprising:
a housing formed at on lateral thereof with a first opening that intercommunicates with an inner accommodating space;
at least one carrying mechanism, installed in the inner accommodating space through the first opening of the housing, the carrying mechanism further comprising:
a carrying seat, configured to carry at least one motherboard;
a first cover plate, perpendicularly connected with the carrying seat, when the carrying mechanism is installed in the inner accommodating space of the housing, the first cover plate rightly covering the first opening so as to prevent foreign matters from entering the inner accommodating space of the housing;
at least two retaining plates, settled at two sides of the first cover plate, when the carrying seat is installed in the inner accommodating space of the housing, the two retaining plates contacting surfaces of the housing at two sides of the first opening, so as to position the carrying mechanism at a specific position without sway or displacement, and allow a user to exert a force on the two retaining plates to draw out the carrying mechanism form the inner accommodating space of the housing; and
at least two fastening members, arranged at two sides of the carrying seat, each of the two fastening members having a first notch tailed by a bent segment provided at an end far from the first cover plate; and
at least two urging units, pivotally provided at two opposite inner lateral surfaces of the housing adjacent to the first opening and each having:
a second notch, configured to engage with the bent segment of a corresponding said fastening members; and
a exerting portion, having a through hole that allows the user to exert a force thereon to drive the urging unit to rotate, wherein when the urging unit is rotated, engagement between the second notch and the bent segment makes the fastening member be ejected out of the housing and the carrying mechanism is ejected from the housing simultaneously.

2. The server of claim 1, wherein the housing has a second opening for allowing the user to access articles inside the inner accommodating space for inspection and maintenance.

3. The server of claim 2, further having a second cover plate configured to cover the second opening for protecting the articles in the inner accommodating space.

4. The server of claim 3, wherein the second cover plate is fastened to the housing by a means selecting from the group consisting of screws, soldering, magnetic attraction and wedge means.

5. The server of claim 1, wherein the motherboard is provided thereon with at least one electronic device for extension of functions of the server.

6. The server of claim 5, wherein the electronic device is selected from the group consisting of a central processing unit (CPU), a hard drive, a random access memory (RAM), a fan and a network interface card.

7. A server with a replaceable module, the server comprises:
a housing formed at on lateral thereof with a first opening that intercommunicates with an inner accommodating space;
at least one carrying mechanism, installed in the inner accommodating space through the first opening of the housing, the carrying mechanism further comprising:
a carrying seat, configured to carry at least one motherboard;
a first cover plate, perpendicularly connected with the carrying seat, when the carrying mechanism is installed in the inner accommodating space of the housing, the first cover plate rightly covering the first opening so as to prevent foreign matters from entering the inner accommodating space of the housing;
at least two retaining plates, settled at two sides of the first cover plate, when the carrying seat is installed in the inner accommodating space of the housing, the two retaining plates contacting surfaces of the housing at two sides of the first opening, so as to position the carrying mechanism at a specific position without sway or displacement, and allow a user to exert a force on the two retaining plates to draw out the carrying mechanism form the inner accommodating space of the housing; and
at least two fastening members, arranged at two sides of the carrying seat, each of the two fastening members having a first notch tailed by a bent segment provided at an end far from the first cover plate; and
at least two urging units, pivotally provided at two opposite inner lateral surfaces of the housing adjacent to the first opening and each having:
a second notch, configured to engage with the bent segment of a corresponding said fastening members; and
a exerting portion, having a rotational post that allows the user to exert a force thereon to drive the urging unit to rotate, wherein when the urging unit is rotated, engagement between the second notch and the bent segment makes the fastening member be ejected out of the housing and the carrying mechanism is ejected from the housing simultaneously.

8. The server of claim 7, wherein the housing has a second opening for allowing the user to access articles inside the inner accommodating space for inspection and maintenance.

9. The server of claim 8, further having a second cover plate configured to cover the second opening for protecting the articles in the inner accommodating space.

10. The server of claim 9, wherein the second cover plate is fastened to the housing by a means selecting from the group consisting of screws, soldering, magnetic attraction and wedge means.

11. The server of claim 7, wherein the motherboard is provided thereon with at least one electronic device for extension of functions of the server.

12. The server of claim 11, wherein the electronic device is selected from the group consisting of a central processing unit (CPU), a hard drive, a random access memory (RAM), a fan and a network interface card.

13. A server with a replaceable module, the server comprises:
a housing formed at on lateral thereof with a first opening that intercommunicates with an inner accommodating space;
at least one carrying mechanism, installed in the inner accommodating space through the first opening of the housing, the carrying mechanism further comprising:
a carrying seat, configured to carry at least one motherboard;
a first cover plate, perpendicularly connected with the carrying seat, when the carrying mechanism is installed in the inner accommodating space of the housing, the first cover plate rightly covering the first opening so as to prevent foreign matters from entering the inner accommodating space of the housing;
at least two fastening members, arranged at two sides of the carrying seat, each of the two fastening members having a first notch tailed by a bent segment provided at an end far from the first cover plate; and
at least one pulling handles, arranged at an outer surface of the first cover plate, for allowing a user to exert a force thereon to draw out the carrying mechanism from the inner accommodating space of the housing, or to push the carrying mechanism into the inner accommodating space of the housing; and
at least two urging units, pivotally provided at two opposite inner lateral surfaces of the housing adjacent to the first opening and each having:
a second notch, configured to engage with the bent segment of a corresponding said fastening members; and
a exerting portion, having a through hole that allows the user to exert a force thereon to drive the urging unit to rotate, wherein when the urging unit is rotated, engagement between the second notch and the bent segment makes the fastening member be ejected out of the housing and the carrying mechanism is ejected from the housing simultaneously.

14. The server of claim 13, wherein the housing has a second opening for allowing the user to access articles inside the inner accommodating space for inspection and maintenance.

15. The server of claim 14, further having a second cover plate configured to cover the second opening for protecting the articles in the inner accommodating space.

16. The server of claim 15, wherein the second cover plate is fastened to the housing by a means selecting from the group consisting of screws, soldering, magnetic attraction and wedge means.

17. The server of claim 13, wherein the motherboard is provided thereon with at least one electronic device for extension of functions of the server.

18. The server of claim 17, wherein the electronic device is selected from the group consisting of a central processing unit (CPU), a hard drive, a random access memory (RAM), a fan and a network interface card.
